(19) United States
(12) Patent Application Publication
(10) Pub. No.: US 2026/0045397 A1
(43) Pub. Date: Feb. 12, 2026

(54) METHOD FOR PREPARING HIGH-PERFORMANCE REBCO HIGH-TEMPERATURE BULK SUPERCONDUCTOR BASED ON LAYERED PRECURSOR PELLET

(71) Applicant: SOUTHWEST JIAOTONG UNIVERSITY, Chengdu (CN)

(72) Inventors: Zigang DENG, Chengdu (CN); Xiwen ZHANG, Chengdu (CN); Tingting LI, Chengdu (CN)

(73) Assignee: SOUTHWEST JIAOTONG UNIVERSITY, Chengdu (CN)

(21) Appl. No.: 19/359,731

(22) Filed: Oct. 16, 2025

Related U.S. Application Data
(63) Continuation of application No. PCT/CN2025/101354, filed on Jun. 17, 2025.

(30) Foreign Application Priority Data
Jun. 25, 2024 (CN) 202410829555.0

(51) Int. Cl. H01F 6/04; C30B 11/14; C30B 29/22; C30B 33/02; H01F 1/055

(52) U.S. Cl. CPC H01F 6/04; C30B 11/14; C30B 29/225; C30B 33/02; H01F 1/0557

(57) ABSTRACT

A method for preparing a high-performance REBCO high-temperature bulk superconductor based on a layered precursor pellet includes: obtaining original reagents with preset molar ratios, and preparing original powders by a solid-phase sintering method; preparing three types of precursor powder combinations by mixing the original powders with preset molar ratios; pressing and stacking the precursor powder combinations to obtain a combined precursor pellet, pressing buffer precursor powders to obtain a buffer layer; processing an REBCO original seed crystal, the combined precursor pellet and the buffer layer based on a preset top-seeded melt texture growth method to obtain an initial REBCO high-temperature bulk superconductor; and performing annealing treatment according to the initial REBCO high-temperature bulk superconductor to obtain a final REBCO high-temperature bulk superconductor. The method achieves the refinement of the second phase particles in the solid solution by the modified precursor powders, and improves the superconducting performance of the bulk material.

### CROSS REFERENCE TO THE RELATED APPLICATIONS

This application is the continuation application of International Application No. PCT/CN2025/101354, filed on Jun. 17, 2025, which is based upon and claims priority to Chinese Patent Application No. 202410829555.0, filed on Jun. 25, 2024, the entire contents of which are incorporated herein by reference.

### TECHNICAL FIELD

The present application relates to the technical field of high-temperature superconducting materials, and specifically, to a method for preparing a high-performance REBCO high-temperature bulk superconductor based on a layered precursor pellet.

### BACKGROUND

In the field of superconducting materials, rare-earth barium copper oxide (REBCO, RE represents light rare earth elements, such as Y, Gd, Sm, and Nd) high-temperature bulk superconductors have attracted widespread attention and favor in the fields of energy, transportation, medical care due to characteristics of high superconducting transition temperature, high critical current density and high critical magnetic field. Since the advent of REBCO high-temperature bulk superconductors, scientists have conducted in-depth research and exploration on the preparation methods of REBCO high-temperature bulk superconductors to continuously improve the performance of the materials. However, current preparation techniques face significant challenges. During the growth of REBCO bulk superconductors, RE211 (RE₂BaCuOx) particles in the melt system are embedded in the RE123 (REBa₂Cu₃O_{7-δ}) matrix, forming pinning centers that play a decisive role in superconducting performance. To improve the superconducting performance of bulk superconductors, RE211 particles need to be refined and evenly distributed. However, although the existing mixed precursor powder (MPP) method may refine the particle size of RE211 particles and optimize particle distribution, the introduction of additional oxygen leads to severe pore distribution inside the final sample, which deteriorates the mechanical performance of the bulk superconductor and affects reliability in practical applications.

Based on the defects of the prior art, a method for preparing a high-performance REBCO high-temperature bulk superconductor based on a layered precursor pellet is needed.

### SUMMARY

An objective of the present application is to provide a method for preparing a high-performance REBCO high-temperature bulk superconductor based on a layered precursor pellet, so as to improve the problems. To achieve the above objective, the present application adopts the following technical solutions.

The present application provides a method for preparing a high-performance REBCO high-temperature bulk superconductor based on a layered precursor pellet, which includes:
obtaining original reagents with preset molar ratios, and preparing original powders by a solid-phase sintering method;
preparing three types of precursor powder combinations by mixing the original powders with preset molar ratios, where the precursor powder combinations include first precursor powder, second precursor powder and buffer layer powder, and a proportion of refined particles in the second precursor powder is larger than that of refined particles in the first precursor powder;
based on a preset REBCO bulk superconductor manufacturing method, pressing and stacking the precursor powder combinations to obtain a combined precursor pellet, and pressing buffer precursor powders to obtain a buffer layer, where the combined precursor pellet includes a second precursor pellet arranged at a bottom and a first precursor pellet coaxially and colaterally placed above the second precursor pellet;
processing an REBCO original crystal seed, the combined precursor pellet and the buffer layer based on a preset top-seeded melt texture growth method to obtain an initial REBCO high-temperature bulk superconductor; and
performing annealing treatment according to the initial REBCO high-temperature bulk superconductor to obtain a final REBCO high-temperature bulk superconductor.

The beneficial effects of the present application are as follows.

The present application optimizes the process and achieves the refinement of the second phase particles in the solid solution by layered preparation and formation of a combined precursor pellet, which improves the superconducting performance of the bulk material, keeps a porosity of about 18%, and enhances the overall performance of the material.

Other features and advantages of the present application will be set forth in the specification below, and will be partly apparent from the specification or may be understood by implementing embodiments of the present application. The objectives and other advantages of the present application may be achieved and obtained through the structures particularly pointed out in the written specification, claims, and drawings.

### BRIEF DESCRIPTION OF THE DRAWINGS

To describe the technical solutions in examples of the present application more clearly, the following briefly describes the accompanying drawings used for describing examples. It should be understood that the accompanying drawings show only some examples of the present application, and therefore should not be considered as a limitation on the scope. Those of ordinary skill in the art may still derive other related drawings from these accompanying drawings without creative efforts.

FIG. 1 is a flow chart of a method for preparing a high-performance REBCO high-temperature bulk superconductor based on a layered precursor pellet according to an embodiment of the present application; and

FIG. 2 is a result graph of porosity versus average number of pores per unit area for various samples.

### DETAILED DESCRIPTION OF THE EMBODIMENTS

To make objectives, technical solutions, and advantages of embodiments of the present disclosure clearer, the following clearly and completely describes the technical solutions in embodiments of the present disclosure with reference to the accompanying drawings in embodiments of the present disclosure. It is clear that the described embodiments are some but not all of embodiments of the present disclosure. Generally, components of embodiments of the present disclosure described and shown in the accompanying drawings herein may be arranged and designed in various configurations. Therefore, the following detailed descriptions of embodiments of the present application provided in the accompanying drawings are not intended to limit the scope of the present application that claims protection, but merely to represent selected embodiments of the present application. All other embodiments obtained by those of ordinary skill in the art based on embodiments of the present application without creative efforts shall fall within the protection scope of the present application.

It should be noted that similar reference numerals and letters indicate similar items in the following drawings, and therefore, once an item is defined in one of the drawings, no further definition or explanation is required in the following drawings. Meanwhile, in the description of the present application, the terms “first”, “second” and the like are used only for distinguishing the description, and may not be construed as indicating or implying the relative importance.

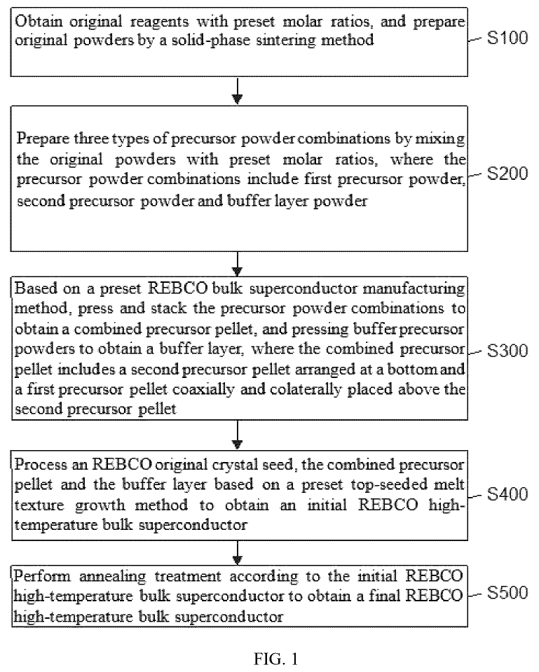

As shown in FIG. 1, this embodiment provides a method for preparing a high-performance REBCO high-temperature bulk superconductor based on a layered precursor pellet, where RE in the REBCO high-temperature bulk superconductor is selected from rare earth elements such as Y, Gd, Sm, and Nd. This method includes step S100, step S200, step S300, step S400, and step S500.

Step S100: Original reagents with preset molar ratios are obtained, and original powders is prepared by the solid-phase sintering method.

It should be noted that the step S100 includes step S110, step S120, and step S130.

Step S110: Three parts of the original reagents are weighed according to the molar ratios of RE₂O₃:BaCO₃:CuO=1:4:6, 1:1:1 and 0:2:3;

Step S120: The three parts of original reagents are mixed, and RE123 original powder, RE211 original powder and RE023 original powder are prepared; and

Step S130: The RE123 original powder, the RE211 original powder and the RE023 original powder are prepared by a solid-phase sintering method to obtain the purified RE123 powder, RE211 powder and RE023 powder.

It may be appreciated that solid-phase sintering is a process in which powdered materials are combined with one another and a dense material is formed without melting by heating the materials to their solid phase reaction temperature. For the preparation of REBCO bulk superconductors, the solid-phase sintering method is helpful for improving the purity and crystallinity of the original powder, thereby optimizing the subsequent processing and performance. It should be noted that the step S130 includes step S131 and step S132.

Step S131: The RE123 original powder is sintered in an air environment at 920° C. for 48 h, the RE211 original powder is sintered in an air environment at 930° C. for 48 h, and the RE023 original powder is sintered in an air environment at 880° C. for 48 h to obtain a sintered RE123 powder block, a sintered RE211 powder block and a sintered RE023 powder block.

Step S132: The sintered RE123 powder block, the sintered RE211 powder block and the sintered RE023 powder block are ground and sintered three times to obtain purified RE123 powder, RE211 powder and RE023 powder.

Step S200: Three types of precursor powder combinations is prepared by mixing the original powders with preset molar ratios, where the precursor powder combinations include first precursor powder, second precursor powder and buffer layer powder, and a proportion of refined particles in the second precursor powder is larger than that of refined particles in the first precursor powder.

It should be noted that the first precursor powder consists of RE123 and RE211, and is conventional precursor powder (CPP) with a relatively large particle size. The second precursor powder consists of RE200 and RE023, and is modified precursor powder (MPP). It should be noted that the step S200 includes step S210, step S220, and step S230.

Step S210: The RE123 powder and the RE211 powder are weighed and mixed according to a molar ratio of 1:0.35, and 1 wt % of CeO₂ powder is added into the mixed powder for mixing treatment to obtain the first precursor powder.

Step S220: The RE200 powder and the RE023 powder are weighed and mixed according to a molar ratio of 0.72:1, and 1 wt % of CeO₂ powder is added into the mixed powder for mixing treatment to obtain the second precursor powder.

Step S230: The RE123 powder and the RE211 powder are weighed and mixed according to a molar ratio of 1:0.4, and 1 wt % of CeO₂ powder is added into the mixed powder for mixing treatment to obtain the buffer layer powder.

Step S300: Based on a preset REBCO bulk superconductor manufacturing method, the precursor powder combinations are pressed and stacked to obtain a combined precursor pellet, buffer precursor powders are pressed to obtain a buffer layer, where the combined precursor pellet includes a second precursor pellet arranged at a bottom and a first precursor pellet coaxially and colaterally placed above the second precursor pellet.

It may be appreciated that the first precursor pellet and the second precursor pellet are designed in a layered manner to optimize the microstructure of the bulk superconductor. The second precursor pellet at the bottom contains more refined particles, so that more pinning centers may be formed, and the superconducting performance of a lower layer region is improved. The first precursor pellet at the upper layer functions to provide mechanical strength. It should be noted that the step S300 includes step S310, step S320, step S330, and step S340.

Step S310: 20 g of the first precursor powder is weighed, and the first precursor powder is put into a square mold with a side length of 30 mm for pressurization and pressing to obtain a first precursor pellet;

Step S320: 20 g of the second precursor powder is weighed, and the second precursor powder is put into a square mold with a side length of 30 mm for pressurization and pressing to obtain a second precursor pellet;

Step S330: The first precursor pellet is coaxially and colaterally placed above the second precursor pellet to obtain the combined precursor pellet.

Step S340: 0.25 g of the buffer layer powder is weighed, and the buffer layer powder is put into a cylindrical mold with a diameter of 6 mm for pressurization and pressing to obtain the buffer layer.

Step S400: An REBCO original crystal seed, the combined precursor pellet and the buffer layer are processed based on a preset top-seeded melt texture growth method to obtain an initial REBCO high-temperature bulk superconductor.

It may be appreciated that the top-seeded melt texture growth (TSMG) process is a process for the preparation of high-performance REBCO high-temperature bulk superconductor by a seeded induced growth technique. The melting temperature and the cooling rate are controlled, so that the crystal seed may induce the lower-layer combined precursor pellet to form a textured superconducting phase. It should be noted that the step S400 includes step S410 and step S420.

Step S410: The buffer layer is inserted between the REBCO original crystal seed and the combined precursor pellet to obtain a coaxial combined structure, where the coaxial combined structure includes the REBCO original crystal seed, the buffer layer and the combined precursor pellet coaxially arranged from top to bottom.

It may be appreciated that the coaxial combined structure ensures close contact between the crystal seed, the buffer layer and the precursor pellet, which helps to induce uniform heat conduction and chemical composition diffusion during the growth process. It should be noted that the step S410 includes step S411 and step S412.

Step S411: A 3 mm×3 mm×3 mm REBCO original crystal seed with a smooth base surface is selected, and the base surface of the REBCO original crystal seed is polished to obtain a processed REBCO original crystal seed.

Step S412: A central axis of the processed REBCO original crystal seed perpendicular to the ground corresponds to a central axis of the buffer layer and a central axis of the combined precursor pellet, and the REBCO original crystal seed is placed between the buffer layer and the combined precursor pellet to obtain the coaxial combined structure.

Step S420: The combined structure is placed on an alumina ceramic plate, and the alumina ceramic plate is placed in a high-temperature furnace to perform texture growth in an air atmosphere to obtain an initial REBCO high-temperature bulk superconductor grown by the REBCO original crystal seed induction.

It may be understood that in this step, through melt texture growth, the crystal orientation guiding effect of the original REBCO crystal seed is used to form a high-quality superconducting phase structure and improve the superconducting performance. It should be noted that the step S420 includes step S421, step S422, and step S423.

Step S421: A temperature in the high-temperature furnace is increased from room temperature to 900° C. for 1 h, the temperature is kept for 3 h, then heating is performed for 1 h, the temperature in the high-temperature furnace is increased to 1055° C., and the temperature is kept for 1 h.

Step S422: The temperature in the furnace is reduced to 1005° C. within 30 min, and the temperature of the furnace is reduced at a cooling rate of 0.2 K/h to 0.4 K/h, so that the REBCO original crystal seed in the furnace induces the combined precursor pellet to grow for 100 h.

It should be noted that the above temperature procedure is suitable for preparing YBCO bulk superconductors by using a top-seeded melt texture growth method, where the top crystal seed is a samarium barium copper oxide (SmBCO) crystal seed.

In other embodiments, for example, a GdBCO bulk superconductor is prepared by a top crystal seed (SmBCO) melt-growth method, and the temperature procedure for texture growth is as follows: heating to 900° C. from room temperature for 1 h, and keeping the temperature for 3 h; then, heating for 1 h to the highest temperature (Tm) of 1055° C., and keeping the temperature for 1 h; rapidly reducing the furnace temperature to 1045° C. within 10 min; then, reducing the furnace temperature at a cooling rate of 0.3 K/h to 0.6 K/h, so that the GdBCO sample in the furnace slowly grows for 100 h; after the growth of the sample is completed, reducing the furnace temperature for 3 h to the room temperature, and obtaining the GdBCO high-temperature bulk superconductor.

Similarly, an SmBCO bulk superconductor is prepared by a top crystal seed (NdBCO) melt-growth method, and the temperature procedure for texture growth is as follows: heating to 900° C. from room temperature for 1 h, and keeping the temperature for 3 h; then, heating for 1 h to the highest temperature (Tm) of 1075° C., and keeping the temperature for 1 h; rapidly reducing the furnace temperature to 1060° C. within 10 min; then, reducing the furnace temperature at a cooling rate of 0.3 K/h to 0.6 K/h, so that the SmBCO sample in the furnace slowly grows for 100 h; after the growth of the sample is completed, reducing the furnace temperature for 3 h to the room temperature, and obtaining the SmBCO high-temperature bulk superconductor.

Step S423: After growth of a sample is completed, the temperature of the high-temperature furnace is reduced to room temperature within 3 h.

Specifically, according to the combined precursor pellet during the growth process, the first precursor pellet (CPP layer) on the upper layer consists of RE123 and RE211, and the second precursor pellet (MPP layer) on the lower layer consists of RE200 and RE023. At high temperatures, RE123 in the CPP layer undergoes non-uniform melting and transforms into a combination of micron-sized RE211 solid phase and RE023 liquid phase. Since RE211 particles occupy a higher volume fraction in the CPP layer, a solid phase skeleton is formed in the liquid phase, while the MPP layer below mainly consists of RE023 liquid phase, in which RE200 exists in the form of nanometer size. Therefore, when the precursor pellet is heated, with the non-uniform melting of RE123, the solid phase skeleton of the CPP layer gradually increases, and the liquid phase of the MPP layer below carries the RE200 particles to penetrate the solute upward, and reacts with the liquid phase in the CPP layer to generate extremely fine RE211 particles. Since the oxygen generated in this process is closer to the edge of the bulk material, it is easier for oxygen to escape from the solid solution, and the porosity of the initial REBCO high-temperature bulk superconductor (C-MPP sample) is reduced. Since RE200 and RE023 generate extremely fine RE211 particles, which form more pinning centers with the RE123 matrix, the superconducting performance of the C-MPP sample is also increased.

Step S500: The annealing treatment is performed according to the initial REBCO high-temperature bulk superconductor to obtain a final REBCO high-temperature bulk superconductor.

In this step, the content and distribution of oxygen in the superconducting phase are adjusted through the post-heat treatment of oxygen annealing, the crystallization state of the superconducting phase is optimized, and the superconducting performance of the bulk superconductor is improved. It should be noted that the step S500 includes step S510 and step S520.

Step S510: The initial REBCO high-temperature bulk superconductor is ground and polished to obtain a pretreated bulk material.

Step S520: The pretreated bulk material is put into a high-temperature furnace with flowing oxygen atmosphere, and oxygen annealing is performed for 200 h at a temperature of 450° C. to obtain the final REBCO high-temperature bulk superconductor.

Further, after the REBCO high-temperature bulk superconductor is prepared, the method also includes the step of performing performance test on the final REBCO high-temperature bulk superconductor (C-MPP sample). To illustrate the superiority of the prepared samples in performance, two bulk materials are prepared under the same conditions using the traditional precursor powder formula and the refined precursor split formula and process, which are respectively labeled as a CPP sample and an MPP sample.

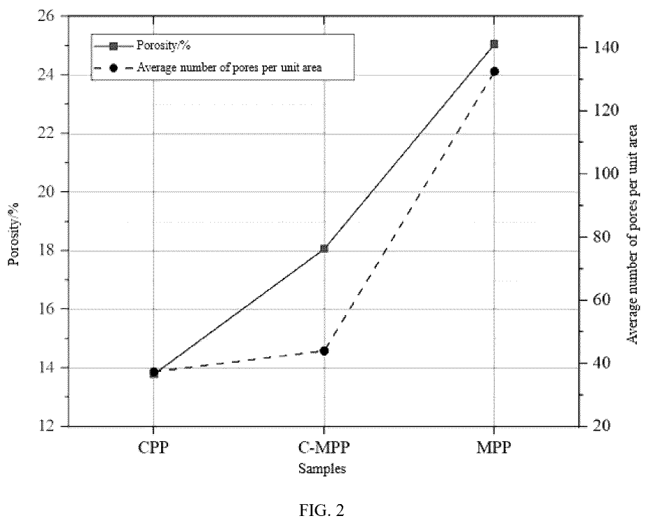

The performance test method of the REBCO bulk superconductor covers porosity characterization and magnetic levitation force characterization. First, porosity characterization is performed by optical observation of the bulk material along the a-c cross section and the use of image processing software to accurately measure and compare the average size and volume fraction of the pores. As shown in FIG. 2, the C-MPP sample shows significant advantages over the traditional MPP sample, significantly reducing the number of pores and porosity, and improving the mechanical performance and application potential of the bulk superconductor.

In addition, the magnetic levitation force characterization evaluates the magnetic performance of the bulk superconductor by using the zero-field cold magnetization method. This method involves fixing the sample on a permanent magnetic track and measuring the magnetic levitation force of the sample at different heights through liquid nitrogen cooling and a specific magnetization process. The test results are shown in Table 1. Based on the force-area density and force-volume density data of different samples, the superconducting performance of C-MPP samples may be accurately evaluated, proving that the C-MPP sample effectively improves the force-area/volume density of samples on the basis of CPP and is on par with the MPP sample, thereby improving the superconducting performance of the bulk superconductor while ensuring mechanical performance.

TABLE 1
Force-area density and force-volume density of different samples

| | | | | Force-area | Force-volume |
|---|---|---|---|---|---|
| | | | Magnetic | density/ | density/ |
| | a-b | Volume/ | levitation | (10⁻¹N/ | (10⁻²N/ |
| Sample | area/mm² | mm³ | force/N | mm²) | mm³) |
| CPP | 585.31 | 5320.47 | 64.3 | 1.10 | 1.21 |
| C-MPP | 496.39 | 4934.12 | 62.5 | 1.26 | 1.27 |
| MPP | 525.98 | 5580.65 | 70.2 | 1.33 | 1.26 |

In conclusion, this comprehensive test method not only deeply analyzes the structural characteristics and the mechanical performance of the REBCO bulk superconductor, but also effectively evaluates the performance of the REBCO bulk superconductor in practical application, thereby providing important theoretical support and experimental basis for further optimization and wide application of the technology.

The exemplary embodiments of the process described in detail above should be noted that those skilled in the art may make modifications and variations to the process without inventive step in the preparation of the REBCO bulk superconductor. Therefore, the technical solutions obtained by logical analysis, reasoning and trial based on the concept of the process method and the prior art by those skilled in the art, such as using NdBCO with higher melting point to grow SmBCO and GdBCO high-temperature bulk superconductors with lower melting point, should be within the protection scope of the present application.

1. A method for preparing a high-performance rare-earth barium copper oxide (REBCO) high-temperature bulk superconductor based on a layered precursor pellet, comprising:
obtaining original reagents with preset molar ratios, and preparing original powders by a solid-phase sintering method;
preparing three types of precursor powder combinations by mixing the original powders with preset molar ratios, wherein the three types of precursor powder combinations comprise first precursor powder, second precursor powder and buffer layer powder, and a proportion of refined particles in the second precursor powder is larger than a proportion of refined particles in the first precursor powder;
based on a preset REBCO bulk superconductor manufacturing method, pressing and stacking the three types of precursor powder combinations to obtain a combined precursor pellet, and pressing buffer precursor powders to obtain a buffer layer, wherein the combined precursor pellet comprises a second precursor pellet arranged at a bottom and a first precursor pellet coaxially and colaterally placed above the second precursor pellet;
processing an REBCO original crystal seed, the combined precursor pellet and the buffer layer based on a preset top-seeded melt texture growth method to obtain an initial REBCO high-temperature bulk superconductor; and
performing annealing treatment according to the initial REBCO high-temperature bulk superconductor to obtain a final REBCO high-temperature bulk superconductor.

2. The method for preparing the high-performance REBCO high-temperature bulk superconductor based on the layered precursor pellet according to claim 1, wherein the step of obtaining the original reagents with the preset molar ratios, and preparing the original powders by the solid-phase sintering method comprises:
weighing three parts of the original reagents according to the preset molar ratios of RE₂O₃:BaCO₃:CuO=1:4:6, 1:1:1 and 0:2:3;
mixing the three parts of the original reagents and preparing RE123 original powder, RE211 original powder and RE023 original powder; and
preparing the RE123 original powder, the RE211 original powder and the RE023 original powder by the solid-phase sintering method to obtain purified RE123 powder, purified RE211 powder and purified RE023 powder.

3. The method for preparing the high-performance REBCO high-temperature bulk superconductor based on the layered precursor pellet according to claim 2, wherein the step of preparing the three types of precursor powder combinations by mixing the original powders with the preset molar ratios comprises:
weighing and mixing the purified RE123 powder and the purified RE211 powder according to a molar ratio of 1:0.35 to obtain first mixed powder, and adding 1 wt % of CeO₂ powder into the first mixed powder for mixing treatment to obtain the first precursor powder;
weighing and mixing RE200 powder and the purified RE023 powder according to a molar ratio of 0.72:1 to obtain second mixed powder, and adding 1 wt % of CeO₂ powder into the second mixed powder for mixing treatment to obtain the second precursor powder; and
weighing and mixing the purified RE123 powder and the purified RE211 powder according to a molar ratio of 1:0.4 to obtain third mixed powder, and adding 1 wt % of CeO₂ powder into the third mixed powder for mixing treatment to obtain the buffer layer powder.

4. The method for preparing the high-performance REBCO high-temperature bulk superconductor based on the layered precursor pellet according to claim 2, wherein the step of preparing the RE123 original powder, the RE211 original powder and the RE023 original powder by the solid-phase sintering method to obtain the purified RE123 powder, the purified RE211 powder and the purified RE023 powder comprises:
sintering the RE123 original powder in a first air environment at 920° C. for 48 h to obtain a sintered RE123 powder block, sintering the RE211 original powder in a second air environment at 930° C. for 48 h to obtain a sintered RE211 powder block, and sintering the RE023 original powder in a third air environment at 880° C. for 48 h to obtain a sintered RE023 powder block; and
grinding and sintering the sintered RE123 powder block, the sintered RE211 powder block and the sintered RE023 powder block three times to obtain the purified RE123 powder, the purified RE211 powder and the purified RE023 powder.

5. The method for preparing the high-performance REBCO high-temperature bulk superconductor based on the layered precursor pellet according to claim 2, wherein the step of pressing and stacking the three types of precursor powder combinations to obtain the combined precursor pellet, and pressing the buffer precursor powders to obtain the buffer layer based on the preset REBCO bulk superconductor manufacturing method comprises:
weighing 20 g of the first precursor powder, and putting the first precursor powder into a first square mold with a side length of 30 mm for pressurization and pressing to obtain the first precursor pellet;
weighing 20 g of the second precursor powder, and putting the second precursor powder into a second square mold with a side length of 30 mm for pressurization and pressing to obtain the second precursor pellet;
coaxially and colaterally placing the first precursor pellet above the second precursor pellet to obtain the combined precursor pellet; and
weighing 0.25 g of the buffer layer powder, and putting the buffer layer powder into a cylindrical mold with a diameter of 6 mm for pressurization and pressing to obtain the buffer layer.

6. The method for preparing the high-performance REBCO high-temperature bulk superconductor based on the layered precursor pellet according to claim 2, wherein the step of processing the REBCO original crystal seed, the combined precursor pellet and the buffer layer based on the preset top-seeded melt texture growth method to obtain the initial REBCO high-temperature bulk superconductor comprises:
inserting the buffer layer between the REBCO original crystal seed and the combined precursor pellet to obtain a coaxial combined structure, wherein the coaxial combined structure comprises the REBCO original crystal seed, the buffer layer and the combined precursor pellet coaxially arranged from top to bottom; and
placing the coaxial combined structure on an alumina ceramic plate, and placing the alumina ceramic plate in a high-temperature furnace to perform texture growth in an air atmosphere to obtain the initial REBCO high-temperature bulk superconductor grown by REBCO original crystal seed induction.

7. The method for preparing the high-performance REBCO high-temperature bulk superconductor based on the layered precursor pellet according to claim 6, wherein the step of inserting the buffer layer between the REBCO original crystal seed and the combined precursor pellet to obtain the coaxial combined structure comprises:
selecting a 3 mm×3 mm×3 mm REBCO original crystal seed with a smooth base surface, and polishing the smooth base surface of the 3 mm×3 mm×3 mm REBCO original crystal seed to obtain a processed REBCO original crystal seed; and
corresponding a central axis of the processed REBCO original crystal seed perpendicular to the ground with a central axis of the buffer layer and a central axis of the combined precursor pellet, and placing the processed REBCO original crystal seed between the buffer layer and the combined precursor pellet to obtain the coaxial combined structure.

8. The method for preparing the high-performance REBCO high-temperature bulk superconductor based on the layered precursor pellet according to claim 6, wherein the step of placing the coaxial combined structure on the alumina ceramic plate, and placing the alumina ceramic plate in the high-temperature furnace to perform texture growth in the air atmosphere comprises:
increasing a temperature in the high-temperature furnace from room temperature to 900° C. for 1 h, keeping 900° C. for 3 h, then heating for 1 h, increasing the temperature in the high-temperature furnace to 1055° C., and keeping 1055° C. for 1 h;
reducing the temperature in the high-temperature furnace to 1005° C. within 30 min, and then reducing the temperature of the high-temperature furnace at a cooling rate of 0.2 K/h to 0.4 K/h, so that the REBCO original crystal seed in the high-temperature furnace induces the combined precursor pellet to grow for 100 h; and
after growth of a sample is completed, reducing the temperature of the high-temperature furnace to room temperature within 3 h.

9. The method for preparing the high-performance REBCO high-temperature bulk superconductor based on the layered precursor pellet according to claim 1, wherein RE in the high-performance REBCO high-temperature bulk superconductor is selected from Y, Gd, Sm, and Nd.

10. The method for preparing the high-performance REBCO high-temperature bulk superconductor based on the layered precursor pellet according to claim 1, wherein the step of performing annealing treatment according to the initial REBCO high-temperature bulk superconductor to obtain the final REBCO high-temperature bulk superconductor comprises:
grinding and polishing the initial REBCO high-temperature bulk superconductor to obtain a pretreated bulk material; and
putting the pretreated bulk material into a high-temperature furnace with flowing oxygen atmosphere, and performing oxygen annealing for 200 h at a temperature of 450° C. to obtain the final REBCO high-temperature bulk superconductor.
